(19) United States
(12) Patent Application Publication
(10) Pub. No.: US 2003/0068845 A1
(43) Pub. Date: Apr. 10, 2003

(54) Flash device having trench source line

(76) Inventors: Fu-Yuan Chen, Kaohsiung (TW); Ching-Hsiang Hsu, Hsinchu (TW); Ya-Chin King, Jungli City (TW); Ching-Sung Yang, Changhua (TW); Hsiu-Fen Chou, Changhua (TW); Kung-Hong Lee, Pingtung (TW); Meng-Yi Wu, Fengshan City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/208,804

(22) Filed: Aug. 1, 2002

(30) Foreign Application Priority Data
Oct. 5, 2001 (TW) 090124760

(51) Int. Cl. H01L 21/336

(52) U.S. Cl. 438/197

(57) ABSTRACT

A method for manufacturing a flash device having a trench source line comprises providing a semiconductor substrate. A pad oxide is formed on a substrate, then forming a nitride layer on the pad oxide. The nitride layer and the pad oxide layer are patterned then etching the substrate to form a trench in the substrate. An ion implantation is performed to dope ions into the substrate under the trench to form the trench source line. Next, refilling material is refilled into the trench, followed by performing chemical mechanical polishing to remove a portion of the refilling material to the substrate. A gate dielectric layer, a first doped conductive layer, an inter conductive dielectric layer, a second conductive layer are formed. The first conductive layer, the second conductive layer and the inter conductive dielectric layer are etched to form gate structure. Subsequently, source and drain regions are formed by ion implantation and halo-doped region is formed under the drain regions by ion implantation.

The present invention relates to a semiconductor device, and more specifically, to a flash memory with trench source line.

### BACKGROUND OF THE INVENTION

The semiconductor industry has been advanced to the field of Ultra Large Scale Integrated (ULSI) technologies. The fabrication of the nonvolatile memories also follows the trend of the size reduction. Various nonvolatile memories have been disclosed in the prior art. The nonvolatile memories include various types of devices, such as EPROM (electrically programmable read only memory), and EEPROM (electrically erasable programmable read only memory). Flash memory is one of the segments of nonvolatile memory devices.

The device includes a floating gate to storage charges and an element for electrically placing charge on and removing the charges from the floating gate. One of the applications of flash memory is BIOS for computer. Typically, the high-density nonvolatile memories can be applied as the mass storage of portable handy terminals, solid-state camera and PC cards. That is because that the nonvolatile memories exhibit many advantages, such as a fast access time, low power dissipation, and robustness. Prior art cell array is operated at low voltage 3V/5V for Portable Computing and Telecommunications Applications”. At present, the low voltage flash memory is applied with a voltage of about 3V or 5V during charging or discharging the floating gate. As known in the art, electrical alterability is achieved by Fowler-Nordheim tunneling which is cold electron tunneling through the energy barrier at a silicon-thin dielectric interface and into the oxide conduction band. Typically, the thin dielectric layer is composed of silicon dioxide and the thin silicon dioxide layer allows charges to tunnel through when a voltage is applied to the gate. In order to attain high tunneling efficiency, the thickness of the dielectric between the floating gate and substrate have to be scaled down due to the supply voltage is reduced.

FIG. 1(a) and FIG. 1(b) illustrate the cross sectional views of prior BiNOR. FIG. 1(a) is viewed from the channel direction and FIG. 1(b) is from the width direction at source. As known in the art, the structure includes a floating gate 2, word line (WL), bit line (BL) and source line (SL). The halo-doped region 3 is implanted under the bit line. A p-type halo doped region 3 is used to prevent punch through and acts as the p-well. The dosage at the drain junction is about 1E14-5E15 atoms/cm². The one for the p-type halo doped region 3 is about 1E13-5E14 atoms/cm². During programming mode, the source node and the N-well is floating such that the bias applied on the bit line leads to N-well charge, thereby suffering the serious program disturbance problem. The prior art uses lower dosage for the source (about 5E12-5E13 atoms/cm²) to reduce the problem mentioned above. However, the lower dosage may introduce the issue of increasing electrical resistance, thereby reducing the read current of the device. What is need is a method to solve the prior issue.

### SUMMARY OF THE INVENTION

The object of the present invention is to form a flash having trench source line. The source line is formed in a trench to improve the reduction of the read current and reduce the program disturbance problem.

A method for manufacturing a flash device having a trench source line comprises providing a semiconductor substrate. A pad oxide is formed on a substrate, then forming a nitride layer on the pad oxide. The nitride layer and the pad oxide layer are patterned then etching the substrate to form a trench in the substrate. An ion implantation is performed to dope ions into the substrate under the trench to form the trench source line. Next, refilling material is refilled into the trench, followed by performing chemical mechanical polishing to remove a portion of the refilling material to the substrate. A gate dielectric layer, a first doped conductive layer, an inter conductive dielectric layer, a second conductive layer are formed. The first conductive layer, the second conductive layer and the inter conductive dielectric layer are etched to form gate structure. Subsequently, source and drain regions are formed by ion implantation and halo-doped region is formed under the drain regions by ion implantation

Further comprising the step of forming a linear oxide after the trench etching. Further comprising the step of performing threshold voltage implantation before forming the gate dielectric layer.

Wherein the dopant for the threshold voltage implantation include boron. The first and second conductive layers include polysilicon. The doping source of the halo-doped region includes BF₂. Wherein the dopant for the trench source line implantation includes arsenic, the dosage is about 1E14-5E15 atoms/cm² and the implanting energy is about 20-80 KeV.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1(a) and FIG. 1(b) illustrate the cross sectional views of prior BiNOR according to the prior art.

FIG. 2 is the cell structure according to the present invention.

FIG. 3 is the layout according to the present invention.

FIG. 4 is a cross sectional view of a semiconductor wafer illustrating the step of forming trench source according to the present invention.

FIG. 5 is a cross sectional view of a semiconductor wafer illustrating the steps of forming tunneling oxide and gate structure according to the present invention.

FIG. 6 is a cross sectional view of a semiconductor wafer illustrating the steps of performing ion implantation according to the present invention.

FIG. 7 is a cross sectional view of a semiconductor wafer illustrating the backend steps according to the present invention.

### DETAILED DESCRIPTION OF THE PREFERRED EMBODIMENT

The present invention proposes a novel flash with trench source line. One aspects of the present invention is to form the source line in a trench followed by implanting heavily doped ions into the source line to improve the reduction of the read current. The detail description will be seen as follows.

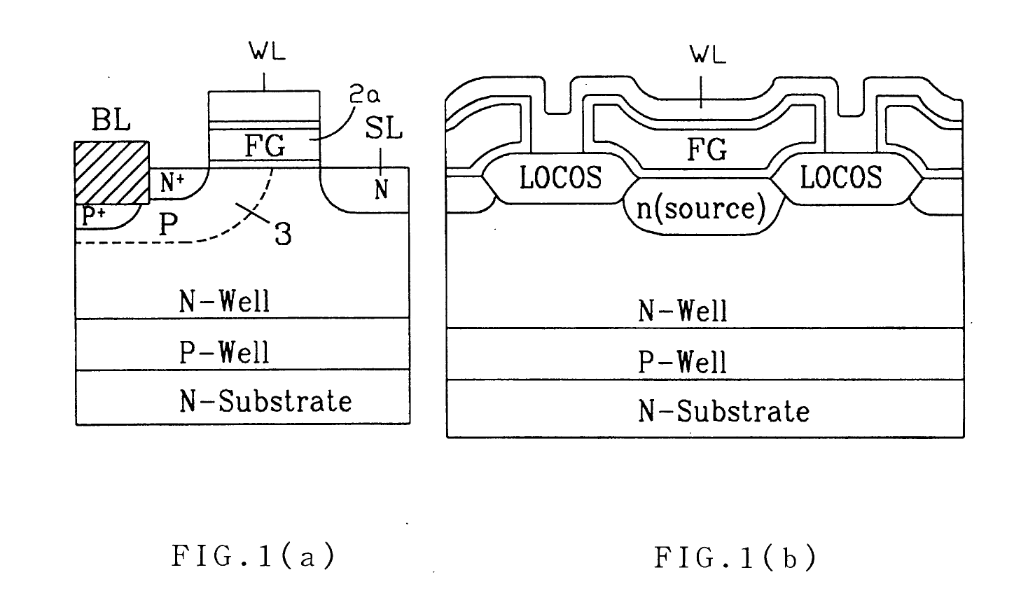

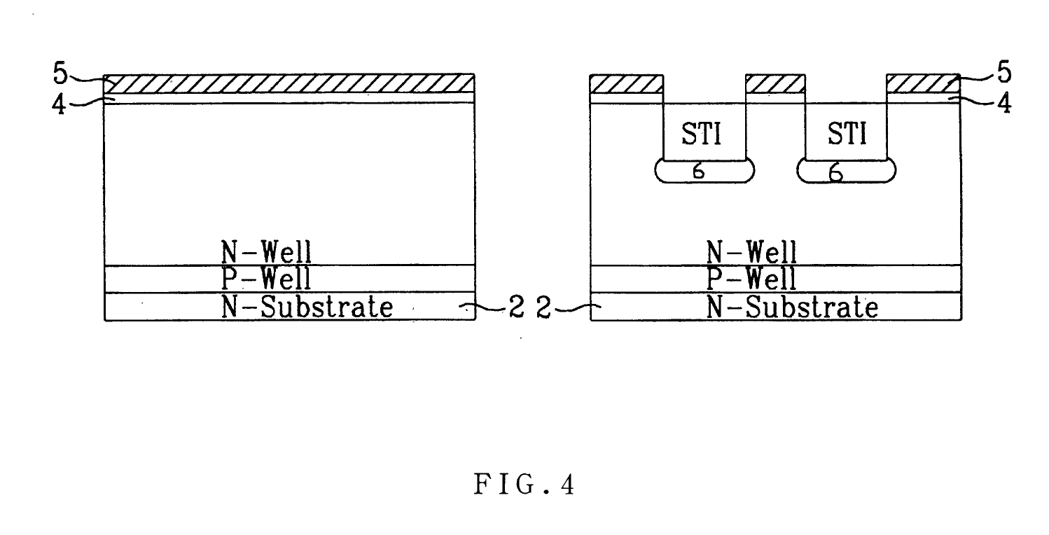

Turning to FIG. 4, a semiconductor substrate is provided for the present invention. A semiconductor substrate 2 has a first conductivity type (P-type) well formed therein. A second conductivity type (N-type) well is formed in the first conductivity type (P-type) well. In a preferred embodiment, as shown in the FIG. 1, a single crystal silicon substrate 2 with a <100> or <111> crystallographic orientation is provided. A thin dielectric layer 4 consisted of silicon dioxide is formed on the substrate 2. Typically, the dioxide 4 can be grown in oxygen ambient at a temperature of about 700 to 1100 degrees centigrade. Other method, such as chemical vapor deposition, can also form the silicon dioxide 4. In the embodiment, the thickness of the silicon dioxide layer 4 is approximately 15-250 angstroms. Subsequently, a silicon nitride layer 5 is formed on the silicon dioxide layer 4. The silicon nitride layer 5 is deposited by any suitable process. For example, Low Pressure Chemical Vapor Deposition (LPCVD), Plasma Enhance Chemical Vapor Deposition (PECVD), High Density Plasma Chemical Vapor Deposition (HDPCVD). In the preferred embodiment, the reaction gases of the step to form silicon nitride layer include SiH₄, NH₃, N₂, N₂O or SiH₂Cl₂, NH₃, N₂, N₂O.

Then, a trench is patterned by using lithography technology and etching in the substrate 2. An optional oxidation step can be used to recover the etched surface. Subsequently, an ion implantation is performed to doped ions into the bottom of the trench for forming source line doped region 6. In the step, As may be used to acts the dopants. The dosage for the implantation is about 1E14-5E15 atoms/cm². The implanting energy is about 20-80 KeV. A refilling material is refilled in the trench. Typically, CVD-oxide may be used as the refilling material and is formed at 400-600 centigrade degrees. Chemical mechanical polishing is performed to remove a portion of the material to the surface of the substrate 2. Shallow trench isolation (STI) 8 is formed in the trench. The source line is formed under the trench followed by implanting heavy dosage of dopants in the doped region. Therefore, the current flows to the source line via the channel for eliminating the program disturbance problem.

Turning 5, boron is implanted to adjust the threshold voltage. A tunneling oxide 12 is formed on the substrate by thermal oxidation at temperature 700-1100 centigrade in oxygen ambient. Other method, such as chemical vapor deposition, can also form the tunneling oxide 12. The thickness of the tunneling oxide 12 is approximately 15-250 angstroms. A first doped polysilicon layer 14 is deposited on the tunneling dielectric layer 12. Generally, the polysilicon layer 14 is chosen from doped polysilicon or in-situ polysilicon. For an embodiment, the doped polysilicon layer 14 is doped by phosphorus using a PH₃ source.

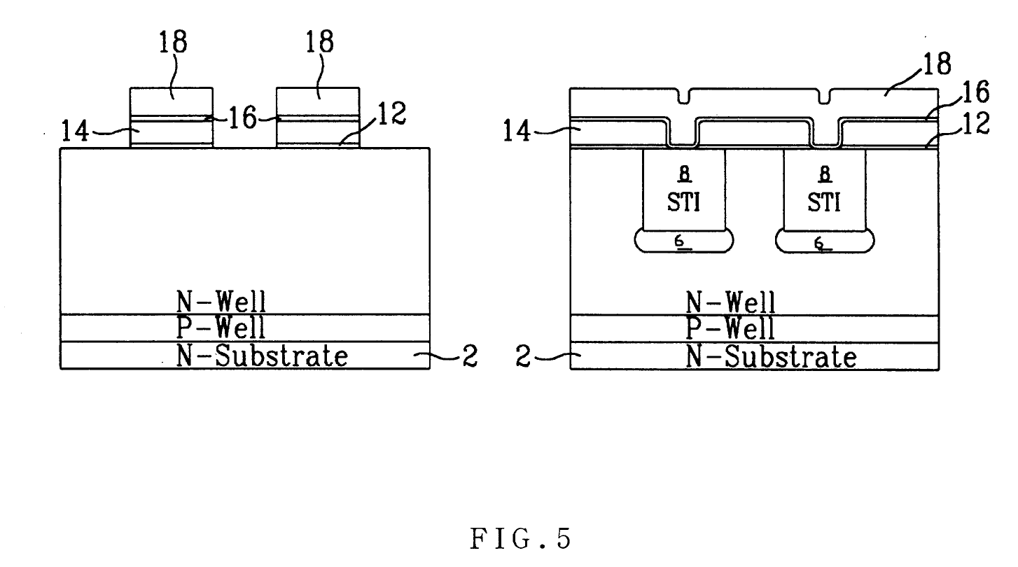

Next, still referring to FIG. 5, standard lithography and etching steps are used to etch the polysilicon layer 14 and the oxide 12. Plasma etching is employed using CF₄+O₂ as the etchant. Subsequently, an inter polysilicon dielectric layer 16, a second polysilicon layer 18 are formed on the first polysilicon layer 14. Next, standard lithography and etching steps are used to etch the polysilicon layer 18, the inter polysilicon dielectric layer 16 and the polysilicon layer 14 to form the control gate. ONO (oxide/nitride/oxide) or NO is used as the inter polysilicon dielectric (IPD) 16.

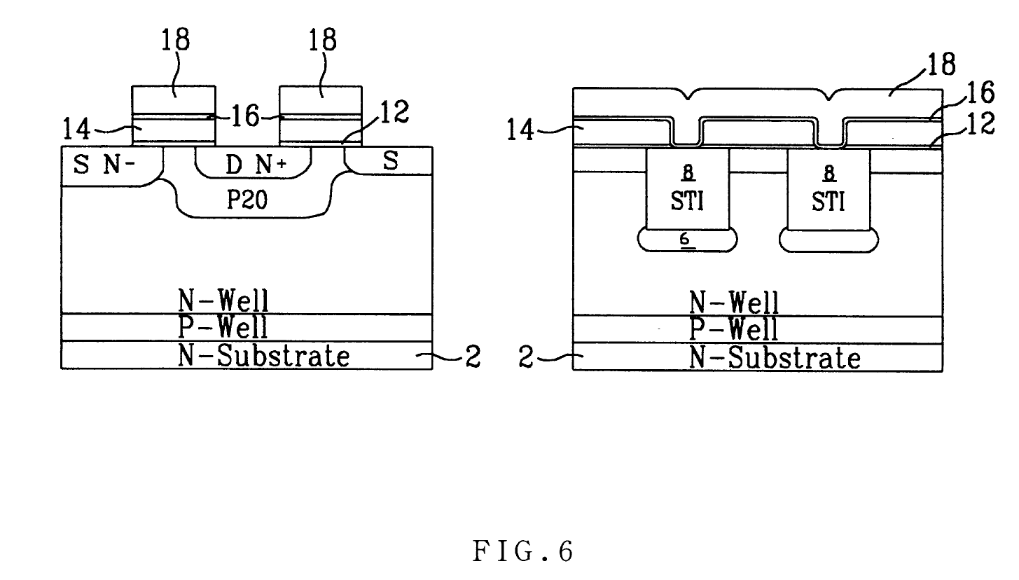

Turning to FIG. 6, an ion implantation is carried out to dope dopants into the substrate 2 by using the gate structure as a mask, thereby forming the source and drain (S/D). Preferred embodiment. N-type ions used, the dosage of the source is about 5E12-5E13 atoms/cm² and the implanting energy is about 15-50 KeV. The dosage of the drain is about 1E14-5E15 atoms/cm² and the implanting energy is about 15-50 KeV. A halo-doped region 20 (p-type) is formed under the drain region. The dosage and the implanting energy for forming the halo-doped region 20 is respectively 1E13-5E14 atoms/cm² and 40-80 KeV.

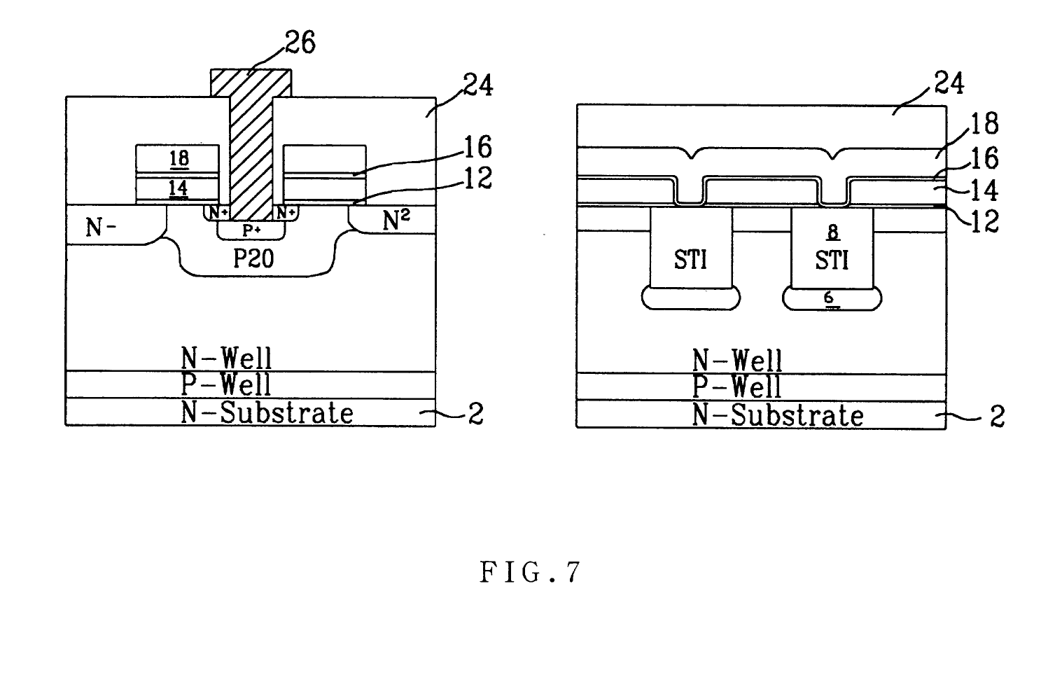

Turning to FIG. 7, an isolation layer 24 is then formed by CVD using TEOS as source at temperature approximately 600-800 centigrade degrees and the pressure is about 0.1 to 10 torrs. A hole is formed in the isolation layer 24 to expose the surface. Ion implantation is employed to implant ions into the substrate through the hole to reduce the resistance. The ion source is BF₂. Metal plug 26 is then formed in the hole.

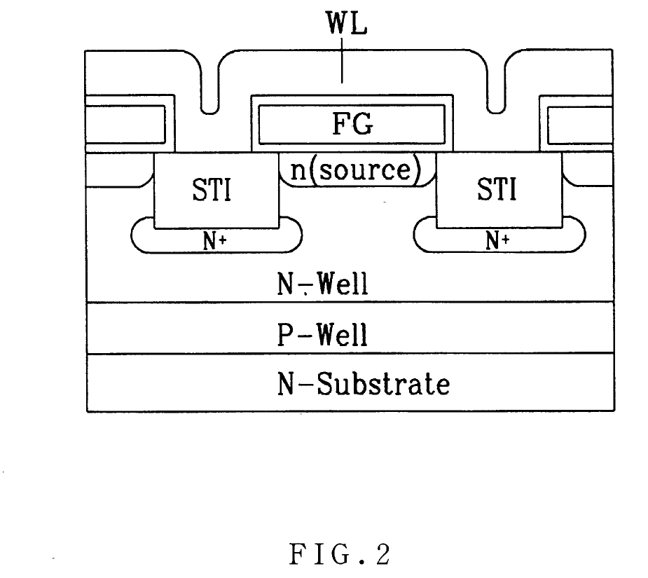

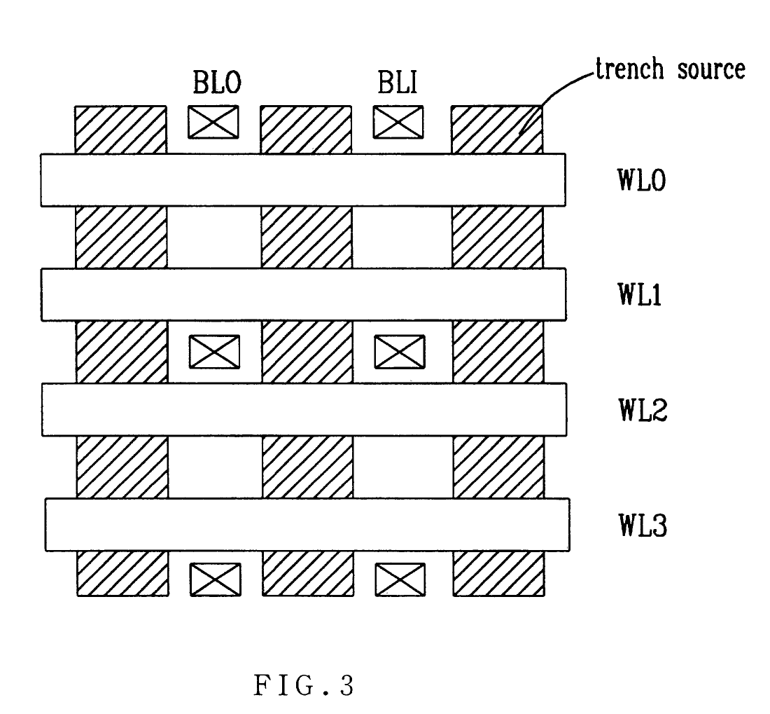

Referring to FIG. 2, the cell includes P-type well formed in the substrate 2. The N-type well is formed in the P-type well. Pluralities of STI are formed in the N-type well. Tunneling oxide 4 is formed on the substrate 2 and floating gate 6 stacked thereon. An inter-poly dielectric layer 16 and the control gate (or word line) 18 are sequentially formed on the floating gate. Trench source line 8 is buried under the STI. The layout according to the present invention is shown in FIG. 3. Pluralities word lines are configured in a parallel form. Trench source lines are formed with parallel and crosses with the word lines.

As will be understood by persons skilled in the art, the foregoing preferred embodiment of the present invention is illustrative of the present invention rather than limiting the present invention. Having described the invention in connection with a preferred embodiment, modification will now suggest itself to those skilled in the art. Thus, the invention is not to be limited to this embodiment, but rather the invention is intended to cover various modifications and similar arrangements included within the spirit and scope of the appended claims, the scope of which should be accorded the broadest interpretation so as to encompass all such modifications and similar structures.

While the preferred embodiment of the invention has been illustrated and described, it will be appreciated that various changes can be made therein without departing from the spirit and scope of the invention.

What is claimed is:

1. A method for manufacturing a flash device having a trench source line, said method comprising the steps of:
forming a pad oxide on a substrate;
forming a nitride layer on said pad oxide;
patterning said nitride layer and said pad oxide layer;
etching said substrate to form a trench in said substrate;
performing an ion implantation to dope ions into said substrate under said trench to form said trench source line;
refilling material into said trench;
performing chemical mechanical polishing to remove a portion of said refilling material to said substrate;
forming a gate dielectric layer on said substrate;
forming a first doped conductive layer on said gate dielectric layer;
forming an inter conductive dielectric layer, a second conductive layer on said first conductive layer;
etching said second conductive layer, said inter conductive dielectric layer and said first conductive layer, to form gate structure;
forming source and drain regions by ion implantation;
forming halo-doped region under said drain regions by ion implantation

2. The method of claim 1, further comprising forming a linear oxide after said trench etching.

3. The method of claim 1, further comprising performing threshold voltage implantation before forming said gate dielectric layer.

4. The method of claim 3, wherein the dopant for said threshold voltage implantation includes boron.

5. The method of claim 1, wherein said inter polysilicon dielectric layer comprises ONO (oxide/nitride/oixde).

6. The method of claim 1, wherein said inter polysilicon dielectric layer comprises NO (nitride/oixde).

7. The method of claim 1, wherein said first and second conductive layers include polysilicon.

8. The method of claim 1, wherein the doping source of said halo-doped region includes BF₂.

9. The method of claim 1, wherein the dopants for said trench source line implantation include arsenic, the dosage is about 1E14-5E15 atoms/cm² and the implanting energy is about 20-80 KeV.

10. A flash device having a trench source line, said device comprising:
Pluralities of STI formed in a substrate;
a tunneling oxide formed on said substrate;
a first conductive layer stacked on said tunneling oxide;
an inter-poly dielectric layer and a second conductive layer sequentially formed on said first conductive layer;
trench source line buried under said pluralities of STI.

11. The device of claim 10, wherein said inter polysilicon dielectric layer comprises ONO (oxide/nitride/oixde) or NO (nitride/oixde).

12. The device of claim 10, wherein said first and second conductive layers include polysilicon.

13. The device of claim 10, wherein said inter-poly dielectric layer includes oxide.

14. The device of claim 10, wherein the dopants for said trench source line include arsenic, the dosage is about 1E14-5E15 atoms/cm² and said trench source line is formed by using implanting energy of about 20-80 KeV.
